(19) United States
(12) Patent Application Publication
(10) Pub. No.: US 2026/0075713 A1
(43) Pub. Date: Mar. 12, 2026

(54) HIGH DENSITY ANISOTROPIC CONDUCTIVE SUBSTRATE (ACS) VIA PRINTED CIRCUIT BOARD CORE

(71) Applicant: BAE Systems Information and Electronic Systems Integration Inc., Nashua, NH (US)

(72) Inventors: Jacob R. Mauermann, Marion, IA (US); Nathaniel P. Wyckoff, Marion, IA (US)

(73) Assignee: BAE Systems Information and Electronic Systems Integration Inc., Nashua, NH (US)

(21) Appl. No.: 18/826,776

(22) Filed: Sep. 6, 2024

(51) Int. Cl. H05K 1/11

(52) U.S. Cl. CPC H05K 1/115; H05K 1/118; H05K 2201/096

(57) ABSTRACT

A universal substrate for a printed circuit board (PCB) package. The universal substrate includes a first end and a second end opposite to the first end, a plurality of conductors located between the first end and the second end, and a nonconductive matrix. The plurality of conductors has a first connection end, a second connection end opposite to the first connection end, and a plurality of conductive pathways defined between the first connection end and the second connection end. The nonconductive matrix surrounds the plurality of conductors and configured to isolate each conductor of the plurality of conductors from one another along an axis that is perpendicular to the plurality of pathways. The universal substrate also includes at least one non-linear section defined between the first connection end and the second connection end.

### TECHNICAL FIELD

The present disclosure relates to universal interconnects or substrates and methods of use.

### BACKGROUND ART

In the electronics market, electronic devices and integrated circuits include numerous products and/or components based on the implementation of these electronic devices and integrated circuits in a desired electrical system or product. Generally, the devices and components of these electronic devices and integrated circuits are positioned in a vertical arrangement to conserve space and the overall footprint of the device or circuit. With such an arrangement, these electronic devices and integrated circuits must precisely connect each device and component in vertical planes at complex positions while avoiding electrical issues.

To combat these difficulties, electronic devices and integrated circuits in the current market may use vertical electrical connection products, such as through substrate vias or through-chip vias, for creating electrical connections. While these products are desired in electronic devices and integrated circuits, these products still provide issues when constructing electronic devices and integrated circuits. In one instance, through substrate vias and other vertical electrical connection products of the like must be formed from a nonconductive base material, such as passivated silicon, glass, and other similar nonconductive base materials. While these nonconductive base materials are suitable, these materials are rather expensive and difficult to source when forming these products. In another instance, through substrate vias and other vertical electrical connection products are designed to a specific circuit or device. With such specificity, the act of manufacturing these through substrate vias and similar products requires fabricating vias and/or channels through the base material in order to lay out conductive tracing and/or material for the various circuits. Such fabrication requires machinery to precisely cut these vias and channels which results in increase costs, increase build times, and loss of leveraging these products into other electronic devices and integrated circuits.

Furthermore, these products are designed to be used with solder balls or plated metal pillars when provided in electronic devices and integrated circuits. When solder balls are used in these electronic devices and integrated circuits, solder balls require individual placement on through substrate vias and the devices, which necessitates precise alignment of a mask or ball drop machine with a part. When plated metal pillars are used in these electronic devices and integrated circuits, the technique of plating requires wet chemicals to be used; however, such techniques of plating can be difficult in acquiring a uniform thickness plating when these products have varying heights and thicknesses.

### SUMMARY OF THE INVENTION

The presently disclosed universal substrate enables designers of electronic devices (such as device-on-device products) or integrated circuits to connect varying types of device and circuits with the universal substrate given a multipurpose pattern and/or configuration. The universal substrate is conductive, either electrically or thermally, in a first or vertical axis, while being nonconductive, either electrically or thermally, in a second axis that is orthogonal to the first axis. The universal substrate also includes a plurality of conductors that is provided in a multipurpose pattern and/or configuration for allowing randomized and/or unplanned electrical connections between devices and components. The universal substrate is also a compliant device that may flex to define one or more non-linear or curvilinear sections based on the structural configuration of the electronic devices included in a device-on-device product or package. As such, the universal substrate disclosed herein addresses some of the inadequacies of previously known through substrate via products.

In one aspect, an exemplary embodiment of the present disclosure may provide a universal substrate for a printed circuit board (PCB) package. The universal substrate includes a first end and a second end opposite to the first end; a plurality of conductors located between the first end and the second end, the plurality of conductors having a first connection end, a second connection end opposite to the first connection end, and a plurality of conductive pathways defined between the first connection end and the second connection end; a nonconductive matrix surrounding the plurality of conductors and configured to isolate each conductor of the plurality of conductors from one another along an axis that is perpendicular to the plurality of pathways; and at least one non-linear section defined between the first connection end and the second connection end; wherein at least two devices of the PCB package have conductivity at any two positions along the first connection end and the second connection end.

This exemplary embodiment or another exemplary embodiment may further include that the at least one non-linear section is a curved section and the at least two coaxial devices of the PCB package are free from being conductive along the at least one non-linear section. This exemplary embodiment or another exemplary embodiment may further include that the at least one non-linear section is a continuous curved section and the at least two coaxial devices of the PCB package are conductive along the at least one non-linear section. This exemplary embodiment or another exemplary embodiment may further include a first connection section defined between the first end of the universal substrate and the at least one non-linear section; and a second connection section defined between the second end of the universal substrate that is opposite to the first end and the at least one non-linear section; wherein the second connection section is positioned above the first connection section. This exemplary embodiment or another exemplary embodiment may further include that the first connection section comprises: a first connection terminal that is a part of the first connection end; and a second connection terminal opposite to the first connection terminal and is a part of the second connection end; and wherein the second connection section comprises: a third connection terminal that is a part of the first connection end; and a fourth connection terminal opposite to the third connection terminal and is a part of the second connection end; wherein the third connection terminal and the fourth connection terminal are each positioned above the first connection terminal and the second connection terminal relative to the at least one non-linear section. This exemplary embodiment or another exemplary embodiment may further include that the at least one non-linear section further comprises: a first non-linear section defined between a first connection section and a second connection section; and a second non-linear section defined between the second connection section and a third connection section; wherein the first connection section, the second connection section, and the third connection section are each substantially linear, and wherein the second connection section is positioned above the first connection section and the third connection section. This exemplary embodiment or another exemplary embodiment may further include that the first connection end is substantially parallel to the second connection end. This exemplary embodiment or another exemplary embodiment may further include that the first connection end is positioned at a range of angles relative to the second connection end from about 0 degrees to about 90 degrees. This exemplary embodiment or another exemplary embodiment may further include that the first connection end is positioned at a range of angles relative to the second connection end from about 0 degrees to about 180 degrees. This exemplary embodiment or another exemplary embodiment may further include that the universal substrate is formed from a resilient, flexible material.

In another aspect, an exemplary embodiment of the present disclosure may provide a printed circuit board (PCB) package. The PCB package includes an integrated circuit (IC) unit placed at a first position in the PCB package; a PCB unit placed at a second position in the PCB package; and a universal substrate placed at a third position in the PCB package and interconnecting the IC unit and PCB with one another; wherein the universal substrate comprises: a first end and a second end opposite to the first end; a plurality of conductors located between the first end and the second end, the plurality of conductors having a first connection end that connects with the IC unit, a second connection end opposite to the first connection end and that connects with the PCB unit, and a plurality of conductive pathways defined between the first connection end and the second connection end; a nonconductive matrix surrounding the plurality of conductors and configured to isolate each conductor of the plurality of conductors from one another along an axis that is perpendicular to the plurality of pathways; and at least one non-linear section defined between the first connection end and the second connection end.

This exemplary embodiment or another exemplary embodiment may further include that the at least one non-linear section is a continuous curved section, and wherein the IC unit and PCB of the PCB package are free from being conductive along the at least one non-linear section or are conductive along the at least one non-linear section. This exemplary embodiment or another exemplary embodiment may further include that the universal substrate further comprises: a first connection section defined between the first end of the universal substrate and the at least one non-linear section; and a second connection section defined between the second end of the universal substrate that is opposite to the first end and the at least one non-linear section; wherein the second connection section is positioned above the first connection section. This exemplary embodiment or another exemplary embodiment may further include that the first connection end is substantially parallel to the second connection end. This exemplary embodiment or another exemplary embodiment may further include that the first connection end is positioned at a range of angles relative to the second connection end from about 0 degrees to about 90 degrees. This exemplary embodiment or another exemplary embodiment may further include that the first connection end is positioned at a range of angles relative to the second connection end from about 0 degrees to about 180 degrees. This exemplary embodiment or another exemplary embodiment may further include that the universal substrate is formed from a resilient, flexible material.

In yet another aspect, an exemplary embodiment of the present disclosure may provide a method. The method comprises steps of: forming at least one non-linear section into a universal substate; connecting an integrated circuit (IC) unit with a first connection end of a universal substrate defined between a first end of the universal substrate and the at least one non-linear section; connecting a printed circuit board (PCB) with a second connection end of the universal substrate defined between a second end of the universal substrate and the at least one non-linear section; and interconnecting the IC unit and the PCB by the universal substrate.

This exemplary embodiment or another exemplary embodiment may further include steps of aligning a first build-up component and a second build-up component with one another; aligning the universal substrate between the first build-up component and the second build-up component; and joining the first build-up component, the second build-up component, and the universal substate together; wherein the step forming the at least one non-linear section into the universal substate further includes that the at least one non-linear section is formed between the first build-up component and the second build-up component. This exemplary embodiment or another exemplary embodiment may further include that the first connection end is positioned at a range of angles relative to the second connection end from about 0 degrees to about 180 degrees.

### BRIEF DESCRIPTION OF THE DRAWINGS

Sample embodiments of the present disclosure are set forth in the following description, are shown in the drawings and are particularly and distinctly pointed out and set forth in the appended claims.

FIG. 1 (FIG. 1) is a first circuit package in accordance with one aspect of the present disclosure, wherein the first circuit package includes a universal substrate defining at least one non-linear section.

FIG. 2 (FIG. 2) is an enlargement view of the region that is highlighted in FIG. 1.

FIG. 3A (FIG. 3A) is an operational view of manufacturing the first circuit package, wherein the universal substrate is aligned with a first build-up component of the first circuit package and a second build-up component of the first circuit package.

FIG. 3B (FIG. 3B) is another operational view continuing from FIG. 3A, wherein the universal substrate is compressed and formed into a non-linear profile by the first build-up component and the second build-up component.

FIG. 3C (FIG. 3C) is another operational view continuing from FIG. 3B, wherein an integrated circuit (IC) unit is connected to the first build-up component.

FIG. 3D (FIG. 3D) is another operational view continuing from FIG. 3C, wherein a printed circuit board (PCB) unit is connected to the second build-up component, and wherein the universal substrates interconnects the integrated circuit (IC) unit and PCB unit with one another.

FIG. 4 (FIG. 4) a second circuit package having two circuit packages in accordance with another aspect of the present disclosure, wherein each circuit package each includes a universal substrate as shown in FIG. 1.

FIG. 5 (FIG. 5) is a fabrication process of fabricating a batch product, wherein a section of the batch product is removed for further wafering processes.

FIG. 6 (FIG. 6) is another fabrication process of fabricating a batch product, wherein a section of the batch product is removed for further wafering processes.

FIG. 6A (FIG. 6A) is a diagrammatic view of the wafered section shown in FIG. 6, wherein the wafered section is connected to a first build-up component and a second build-up component.

FIG. 6B (FIG. 6B) is a diagrammatic view of the wafered section shown in FIG. 6, wherein the wafered section is an interconnect between a first circuit package and a second circuit package.

FIG. 7 (FIG. 7) is another fabrication process of fabricating a batch product, wherein a section of the batch product is removed for further wafering processes.

FIG. 7A (FIG. 7A) is a diagrammatic view of the wafered section shown in FIG. 7, wherein the wafered section is connected to a first build-up component and a second build-up component.

FIG. 7B (FIG. 7B) is a diagrammatic view of the wafered section shown in FIG. 7, wherein the wafered section is an interconnect between a first circuit package and a second circuit package.

FIG. 8 (FIG. 8) is a flowchart of an exemplary method.

Similar numbers refer to similar parts throughout the drawings.

### DETAILED DESCRIPTION

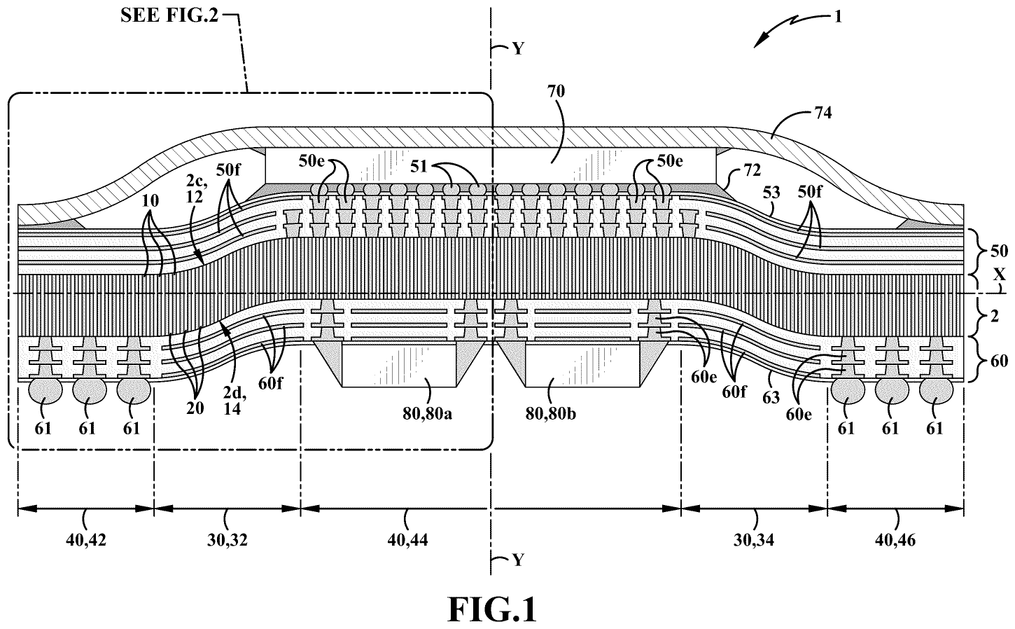

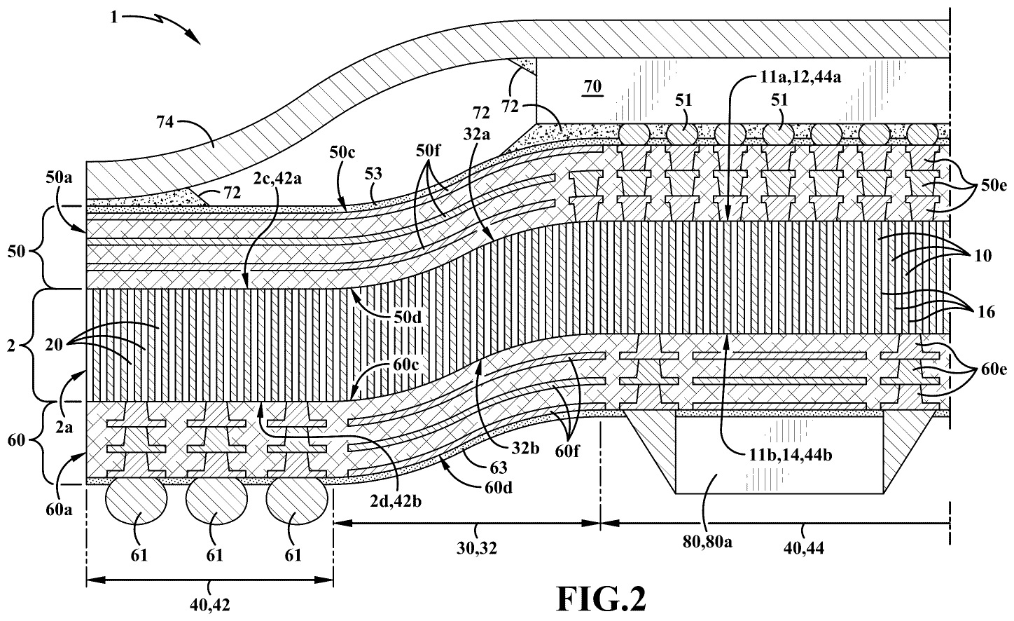

FIGS. 1-2 illustrate a package-on-package system (hereinafter “PoP”) or a device-on-device product that is generally referred to as numeral 1. In particular, PoP 1 includes a universal substrate or universal interconnect that is generally referred to as numeral 2. In the present disclosure, universal substrate 2 may be used to operably engage at least one electronic device and at least another electronic device with one another to interconnect the at least one electronic device and the at least another electronic device for electrical communication. As discussed in greater detail below, universal substrate 2 enables at least one electronic device and at least another electronic device to be engaged with the universal substrate 2 at any location along the universal substrate 2 only if one or more electrical connections of the at least one electronic device and the at least another electronic device are vertically coaxially with one another. Such features and components of universal substrate is discussed in greater detail below.

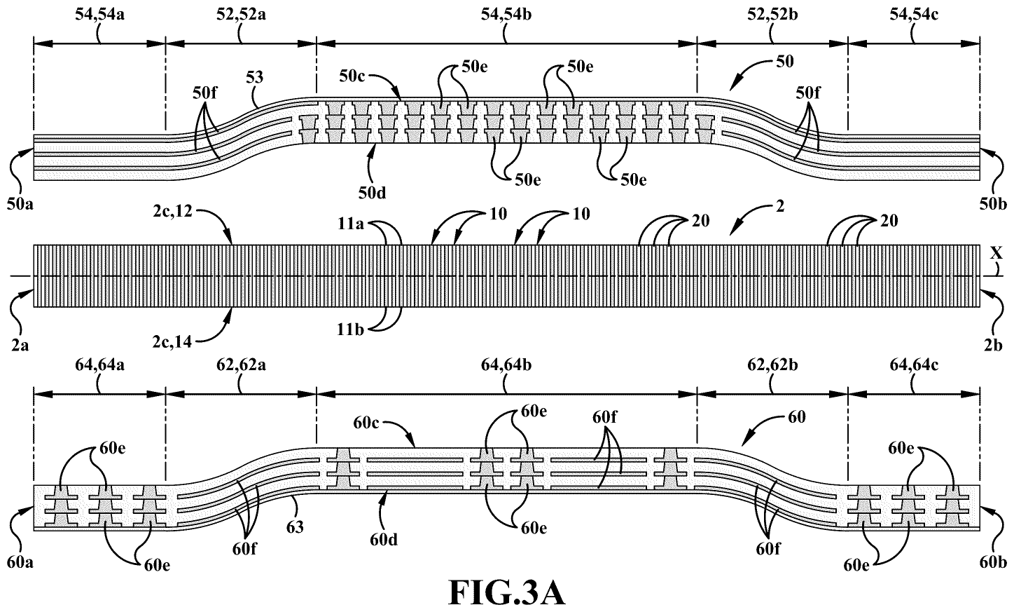

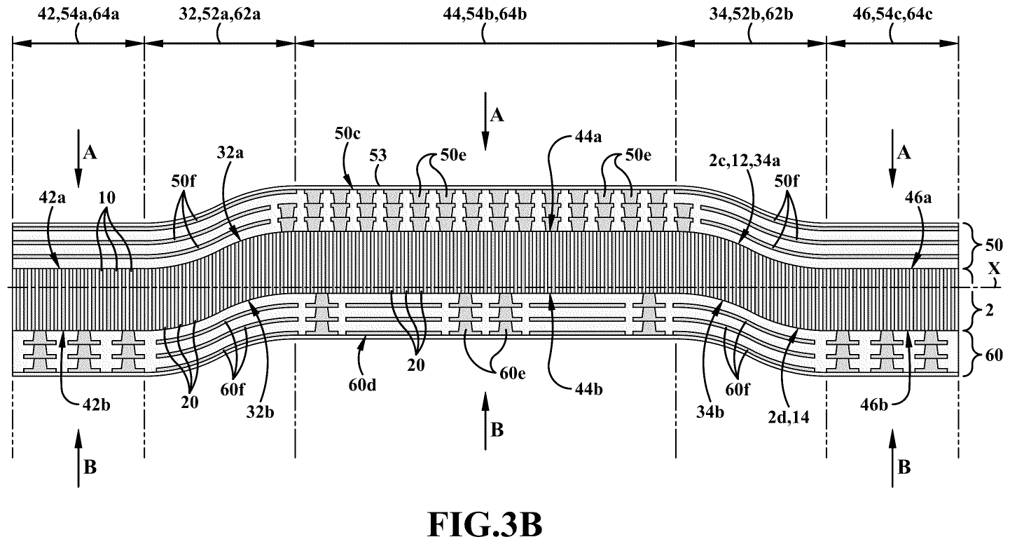

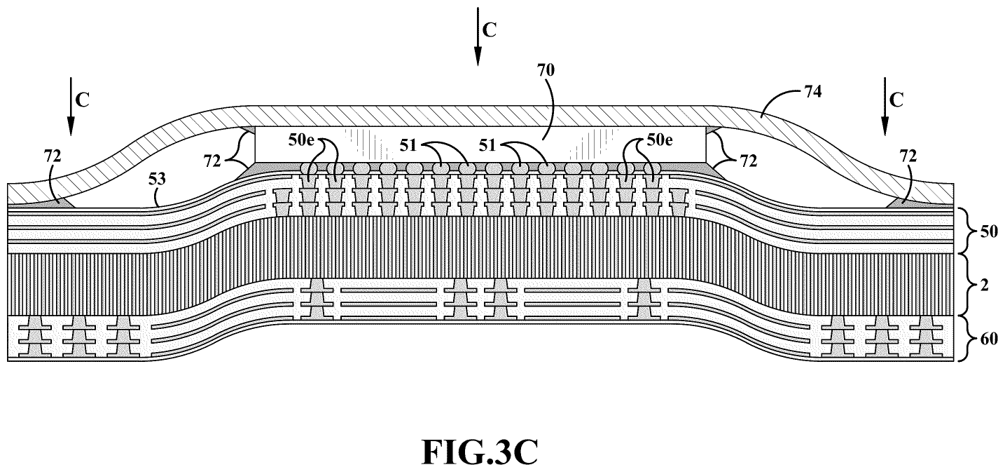

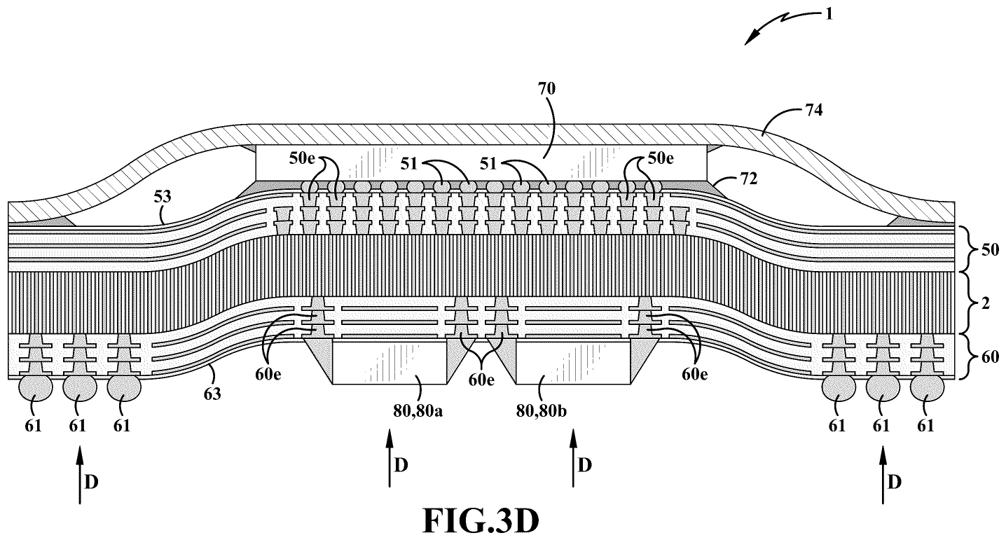

Referring to FIGS. 1 and 3A, universal substrate 2 may include a first end 2a, a second end 2b longitudinally opposite to the first end 2a, and a longitudinal or horizontal axis (denoted by a dotted line labeled “X” in FIG. 1) defined therebetween. Universal substrate 2 may also include a top end 2c positioned vertically above the first end 2a and the second end 2b, a bottom end 2d positioned vertically below the first end 2a and second end 2b, and a vertical axis (denoted by a dotted line labeled “Z” in FIG. 1) defined therebetween.

In one exemplary embodiment, universal substrate 2 may define any suitable length and height dictated by the implementation of universal substrate 2. In one exemplary embodiment, a height (or thickness) of a universal substrate may be at least 100 micrometers. In another exemplary embodiment, a height (or thickness) of a universal substrate may be between at least 100 micrometers up to about at least 1 millimeter.

Universal substrate 2 also includes a plurality of conductors 10. As best seen in FIG. 2, each conductor of the plurality of conductors 10 includes a first connection end 11a that is positioned at the top end 1c of the universal substrate 2. Each conductor of the plurality of conductors 10 also includes a second connection end 11b that is positioned at the bottom end 1d of the universal substrate 2 and is vertically opposite to the first connection end 11a. Each conductor of the plurality of conductors 10 also includes a conductive pathway or axis that extends between the first connection end 11a and the second connection end 11b. In one instance, the conductive pathway of each conductor of the plurality of conductors 10 may provide electrical conductivity between the first connection end 11a and the second connection end 11b to enable electrical communication between at least two devices. In another instance, the conductive pathway of each conductor of the plurality of conductors 10 may provide thermal conductivity between the first connection end 11a and the second connection end 11b to enable heat dissipation.

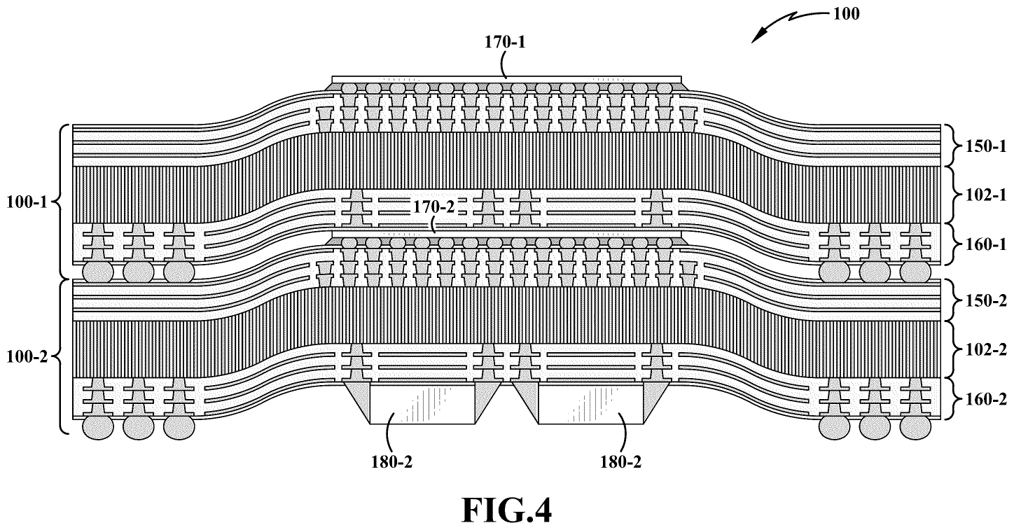

Still referring to the plurality of conductors 10, the plurality of conductors 11 collectively defines a first connection surface 12. As best seen in FIG. 2, the first connection surface 12 spans across the top end 1c of the universal substrate defined along the first connection ends 11a of the plurality of conductors 10. Similarly, the plurality of conductors 11 also collectively defines a second connection surface 14. As best seen in FIG. 4, the second connection surface 14 spans across the bottom end 1d of the universal substrate defined along the second connection ends 11b of the plurality of conductors 10. With such first connection surface 12 and second connection surface 14, a plurality of conductive pathways 16 is then defined between the first connection surface 12 and the second connection surface 14 by the plurality of conductors 10.

In the present disclosure, the plurality of conductors 10 are arranged in a randomized and/or non-uniform configuration. In other exemplary embodiments, a plurality of conductors may be arranged in any suitable configuration dictated by the implementation of the universal substrate 2. In one exemplary embodiment, a plurality of conductors may be arranged in an organized and/or uniform configuration (i.e., aligned in distinct rows and/or columns). In one exemplary embodiment, at least one set of conductors of a plurality of conductors may be arranged in an organized and/or uniform configuration, and at least another set of conductors of the plurality of conductors may be arranged a randomized and/or non-uniform configuration.

It should also be understood that one or more sets of conductors that are a part of the plurality of conductors 10 may define one or more diameters between respective first connection end 11a and second connection end 11b. In one example, each conductor of the plurality of conductors 10 may define a first diameter that is continuous along the entire length of each conductor of the plurality of conductors 10 between the first connection end 11a and second connection end 11b. In another example, each conductor of a first set of conductors defines a first diameter that is continuous along the entire length of each conductor of the first set of conductors. In this same example, each conductor of a second set of conductors defines a second diameter that is continuous along the entire length of each conductor of the second set of conductors where the second diameter is greater than the first diameter. Such differing diameters among the plurality of conductors 10 may be desirable when designers of device-on-device products have devices with different signal densities, and/or different sizes and/or footprints.

Universal substrate 2 also includes a nonconductive matrix or material 20 that operably engages with the plurality of conductors 10. The nonconductive matrix 20 includes a plurality of nonconductive pathways where each nonconductive pathway of the plurality of nonconductive pathways extends longitudinally or transversely between each conductor of the plurality of conductors 10 to prevent any conductivity between adjacent conductors of the plurality of conductors 10. In one instance, a set of first nonconductive pathways may extend between the first end 2a of universal substrate 2 and the second end 2b of universal substrate 2 to prevent any conductivity between adjacent conductors of the plurality of conductors 10 in a longitudinal direction. In another instance, a set of second nonconductive pathways may extend in a transverse direction opposite to the set of first nonconductive pathways to prevent any conductivity between adjacent conductors of the plurality of conductors 10.

By insulating each conductor of the plurality of conductors 10 from one another, each conductor of the plurality of conductors 10 are free from being conductive (either electrically or thermally) in a longitudinal direction or a transverse direction (i.e., along a nonconductive pathway of the plurality of nonconductive pathways). As such, universal substrate 2 is anisotropic by allowing conductivity (either electrical or thermal) in a first direction (i.e., conductive pathway) while preventing conductivity (either electrical or thermal) in a second direction (i.e., nonconductive pathway) that is orthogonal to the first direction.

The structural configuration of the universal substrate 2 is considered advantageous at least because one or more electronic devices or products may be electrically connected at any position along the first connection surface 12 and the second connection surface 14 that is free from using any predetermined electrical voids or apertures formed into either the first connection surface 12 or the second connection surface 14. In the present disclosure, designers of device-on-device products are enabled to connect one or more devices (see FIGS. 1, 3C-3D, 4, 6B, and 7B) by using one or more conductors of the plurality of conductors 10 along the first connection surface 12 and the second connection surface 14. As such, designers of these device-on-device products are free to place devices at any location along the universal substrate 2 as desired without needing to initially create or define predetermined electrical voids or apertures in the universal substrate 2.

The structural configuration of the universal substrate 2 is considered advantageous at least because universal substrate 2 may be manufactured in various ways dictated by the machinery and/or tools available. In one example, universal substrates 2 may be manufactured individually (see FIG. 3A) in a batch process. In another example, a single, monolithic universal substrate 2 may be manufactured in a continuous process where said monolithic universal substrate 2 is cut and/or divided into a plurality of universal substrates.

Universal substrate 2 also includes a set of non-linear sections 30 that is defined along the length of universal substrate 2. As best seen in FIGS. 1-2, universal substrate 2 includes a first non-linear section 32 that has a first connection terminal 32a that is a part of the first connection end 11a, a second connection terminal 32b that is opposite to the first connection terminal 32a and is a part of the second connection end 11b, and an axis defined therebetween. In the present disclosure, universal substrate 2 includes a second non-linear section 34 that is longitudinally opposite to the first non-linear section 32 relative to the longitudinal axis “X” of universal substrate 2. Similar to the first non-linear section 32, second non-linear section 34 has a first connection terminal 34a that is a part of the first connection end 11a, a second connection terminal 34b that is opposite to the first connection terminal 34a and is a part of the second connection end 11b, and an axis defined therebetween.

It should be understood that non-linear sections 32, 34 of the universal substrate 2 may have any suitable cross-sectional shape when viewed from a cross-sectional view (see FIGS. 1-2). In one exemplary embodiment, a non-linear section of a universal substrate discussed herein may have a continuous curvilinear or curved cross-sectional shape when viewed from a cross-sectional view. In another exemplary embodiment, a non-linear section of a universal substrate discussed herein may have an arcuate or round cross-sectional shape when viewed from a cross-sectional view. It should also be understood that a non-linear section of a universal substrate discussed herein may be formed into a desired non-linear shape prior to being connected with electronic devices to assemble a PoP. It should also be understood that a non-linear section of a universal substrate discussed herein may be formed into a desired non-linear shape by one or more electronic devices as the PoP is being assembled due to the universal substrate being made of resilient and/or elastic material that is compliant to and forms to desired shapes of electronic devices or build-up material discussed herein.

As provided herein, the use of “resilient”, “flexible”, or “elastic” in describing a component mentioned herein generally refers to such component being able to change shape as force is applied against said components by one or more separate components of a PoP and may return to substantially the same shape when the force is removed. Additionally, such use of “resilient”, “flexible”, or “elastic” in describing a component mentioned herein also generally refers to such component being compliant with and forming to one or more separate components of a PoP as said separate components apply pressure against the component. Examples of suitable resilient or flexible materials that may be used to manufacture a universal substrate mentioned herein include, but are not limited to, epoxies, polyimides, and other highly insulative materials that include high thermal stability.

Universal substrate 2 may also include a set of linear or planar sections 40 along the length of universal substrate 2. In one example, and as best seen in FIG. 1, universal substrate 2 includes a first linear section 42 that is defined between the first end 2a of universal substrate 2 and the first non-linear section 32. The first linear section 42 includes a first connection terminal 42a that is a part of the first connection end 11a, a second connection terminal 42b that is opposite to the first connection terminal 42a and is a part of the second connection end 11b, and an axis defined therebetween. In this same example, universal substrate 2 includes a second linear section 44 that is defined between the first non-linear section 32 and the second non-linear section 30b. The second linear section 44 includes a first connection terminal 44a that is a part of the first connection end 11a, a second connection terminal 44b that is opposite to the first connection terminal 44a and is a part of the second connection end 11b, and an axis defined therebetween. In this same example, universal substrate 2 also includes a third linear section 46 that is defined between the second end 2b of universal substrate 2 and the second non-linear section 34. The third linear section 46 includes a first connection terminal 46a that is a part of the first connection end 11a, a second connection terminal 46b that is opposite to the first connection terminal 46a and is a part of the second connection end 11b, and an axis defined therebetween.

In the present disclosure, the linear sections 42, 44, 46 included in universal substrate 2 are positioned at different vertical heights relative to the longitudinal axis “X” of universal substrate 2. As best seen in FIGS. 1 and 3B, the second linear section 44 is positioned above the first linear section 42 due to the inclusion of the first non-linear section 32 elevating the second linear section 44. Similarly, and as best seen in FIGS. 1 and 3B, the second linear section 44 is also positioned above the third linear section 46 due to the inclusion of the second non-linear section 34 elevating the second linear section 44. As such, the first linear section 42 and the third linear section 46 are even with one another along the same plane relative to the longitudinal axis “X” of universal substrate 2 while the second linear section 44 is offset from the longitudinal axis “X”of universal substrate 2.

Such structural configuration of the non-linear sections 32, 34 and the linear sections 42, 44, 46 of universal substrate 2 is considered advantageous at least because the universal substrate 2 is able to be an interconnection for two or more electronic devices that have irregular or non-linear structural configurations. As discussed previously, the resiliency and elasticity of universal substrate 2 allows for the creation of one or more non-linear sections in the universal substrate 2 when one or more electronic devices have irregular or non-linear structural configurations. As such, the universal substrate 2 may flex and conform to the electronic device to the geometric profile of the electronic devices that have protruding components or elements extending from the respective electronic device thus creating linear and non-linear sections along universal substrate 2; such conforming by the universal substrate 2 is discussed in greater detail below. In one exemplary embodiment, the universal substrate may also include one or more linear sections and one or more non-linear sections that are formed in universal substrate 2 prior to being assembled with electronic devices to form a PoP.

PoP 1 also includes a first build-up component 50 and a second build-up component 60 that operably engages with the universal substrate 2. As best seen in FIGS. 1-2, the first build-up component 50 includes a first end 50a that is aligned with first end 2a of universal substrate 2 when PoP 1 is assembled, a second end 50b opposite to the first end 50a and aligned with the second end 2b of universal substrate 2 when PoP 1 is assembled, and a longitudinal axis defined therebetween. First build-up component 50 also includes a first connection surface 50c that faces away from the universal substrate 2 and engages with an electronic device of PoP 1, and a second connection surface 50d that faces towards and operably engages with the universal substrate 2.

First build-up component 50 also includes electrical connections 50e that are positioned between the first connection surface 50c and the second connection surface 50d. In the present disclosure, electrical connections 50e enable electrical signals to pass through the first build-up component 50 from the first connection surface 50c to the second connection surface 50d. First build-up component 50 also includes conductive tracing elements 50f that operably engage with one or more electrical connection 50e of first build-up component 50. In the present disclosure, each conductive tracing element 50f is configured interconnect with a first group of electrical connections 50e and a second group of electrical connections 50e that are free from being vertically aligned with one another; stated differently, each conductive tracing element 50f is configured to interconnect groups of electrical connections 50e with one another that are offset from one another. Such interconnections allows for electric or thermal conductivity between devices or components that are offset from one another inside of PoP 1.

PoP 1 may also include solder bump connections 51 that are positioned along a portion of the first connection 50c of first build-up component 50. The solder bump connections 51 operably engage with the electrical connections 50e in order to pass electrical signals from an electronic device that engages with the solder ball connection 51 to the universal substrate 2.

First build-up component 50 also includes one or more non-linear sections 52 and one or more linear or planer sections 54. In the present disclosure, first build-up component 50 includes a first non-linear section 52a and a second non-linear section 52b that are formed between the first end 50a and the second end 50b due to at least one electronic device included in PoP 1. First build-up component 50 also includes three linear sections where a first linear section 54a is positioned between the first end 50a and the first non-linear section 52a, a second linear section 54b positioned between the first non-linear section 52a and the second non-linear section 52b, and a third linear section 54c that is positioned between the second end 50b and the second non-linear section 52b. It should be noted that the structural configuration of the first build-up component 50 matches the structural configuration of the universal substrate 2.

First build-up component 50 may also include a protective layer or coating 53. As best seen in FIG. 2, protective layer 53 may be applied to the first connection surface 50c of first build-up component 50 to protect any conductive tracing elements 50f or other electrical connections provided with first build-up component 50. The protective layer 53 is provided along all non-linear sections 52 of first build-up component 50 and all linear sections 54 of first build-up component 50.

Similar to the first build-up component 50, the second build-up component 60 includes a first end 60a that is aligned with first end 2a of universal substrate 2 when PoP is assembled, a second end 60b opposite to the first end 60a and aligned with the second end 2b of universal substrate 2 when PoP is assembled, and a longitudinal axis defined therebetween. Second build-up component 60 also includes a first connection surface 60c that faces away from the universal substrate 2 and engages with another electronic device of PoP 1, and a second connection surface 60d that faces towards and operably engages with the universal substrate 2.

Second build-up component 60 also includes electrical connections 60e that are positioned between the first connection surface 60c and the second connection surface 60d. In the present disclosure, electrical connections 60e enable electrical signals to pass through the second build-up component 60 from the first connection surface 60c to the second connection surface 60d. Second build-up component 60 also includes conductive tracing elements 60f that operably engage with one or more electrical connection 60e of second build-up component 60. In the present disclosure, each conductive tracing element 60f is configured interconnect with a first group of electrical connections 60e and a second group of electrical connections 60e that are free from being vertically aligned with one another; stated differently, each conductive tracing element 60f is configured interconnect groups of electrical connections 60e with one another that are offset from one another. Such interconnections allows for electric or thermal conductivity between devices or components that are offset from one another inside of PoP 1.

PoP 1 may also include solder ball connections 61 that are positioned along a portion of the first connection 60c of second build-up component 60. The solder ball connections 61 operably engage with the electrical connections 60e in order to pass electrical signals from an electronic device that engages with the solder ball connection 51 to the universal substrate 2.

Second build-up component 60 also includes one or more non-linear sections 62 and one or more linear or planer sections 64. In the present disclosure, second build-up component 60 includes a first non-linear section 62a and a second non-linear section 62b that are formed between the first end 50a and the second end 60b due to at least one electronic device included in PoP 1. Second build-up component 60 also includes three linear sections where a first linear section 64a is positioned between the first end 60a and the first non-linear section 62a, a second linear section 64b positioned between the first non-linear section 62a and the second non-linear section 62b, and a third linear section 64c that is positioned between the second end 60b and the second non-linear section 62b. It should be noted that the structural configuration of the second build-up component 60 matches the structural configuration of the universal substrate 2.

Second build-up component 60 may also include a protective layer or coating 63. As best seen in FIG. 2, protective layer 63 may be applied to the first connection surface 60c of second build-up component 60 to protect any conductive tracing elements 60f or other electrical connections provided with second build-up component 60. The protective layer 63 is provided along all non-linear sections 62 of second build-up component 60 and all linear sections 64 of second build-up component 60.

PoP 1 also includes an integrated circuit (IC) unit or flip clip 70. As best seen in FIG. 1 and FIG. 2, IC unit 70 operably engages with the first build-up component 50, particularly with the electrical connections 50e of the first build-up component 50 via the solder bump connections 51. IC unit 70 is maintained with the first build-up component 50 by an underfill material 72. Additionally, a heat spreader 74 may also operably engage with the IC unit 70 and the first build-up component 50 for dissipating heat from the PoP 1. Underfill material 72 may also be applied to the heat spreader 74 in order to maintain the heat spreader 74 with the IC unit 70.

PoP 1 also includes a package substrate 80. As best seen in FIG. 1, package substrate 80 operably engages with the second build-up component 60, particularly with the electrical connections 60e of the second build-up component 60 via the solder ball connections 61. In the present disclosure, at least two capacitors 80a, 80b or electrical components of package substrate 80 may operably engage with the second build-up component 60. Due to the interconnection capability provided by the universal substrate 2, the IC unit 70 and the capacitors 80a, 80b are in electrical communication with one another. Due the inclusion of the non-linear and/or curvilinear profile of the universal substrate 2, the first build-up component 50, and the second build-up component 60, the capacitors 80a, 80b of package substrate 80 are accommodated without disrupting electrical communication between the IC unit 70 and the capacitors 80a, 80b. While capacitors 80a, 80b are shown with package substrate 80, any suitable electrical device or component included with package substrate 80 may be accommodated due to the design of the first and second build-up components 50, 60 as well as the resiliency and compliance of the universal substrate 2.

Having now discussed the components of PoP 1 that includes universal substrate 2, a method of assembling PoP 1 is discussed in greater detail below.

Initially, universal substrate 2 is aligned between the first build-up component 50 and the second build-up component 60 (see FIG. 3A). At this stage, universal substrate 2 is completely linear and/or planar between the first end 2a to the second end 2b. Without any force applied to the universal substrate 2, universal substrate 2 remains in the linear profile in this particular embodiment. In the present disclosure, first build-up component 50 and second build-up component 60 are each formed into a specific design based on the layout of electrical components provided with the IC unit 70 and the package substrate 80. As discussed previously, first build-up component 50 includes first and second non-linear sections 52a, 52b to accommodate the capacitors 80a, 80b of the package substrate 80, and second build-up component 60 includes matching first and second non-linear sections 62a, 62b to accommodate the capacitors 80a, 80b of the package substrate 80. With such non-linear sections, first build-up component 50 also includes first, second, and third linear sections 54a, 54b, 54c, and second build-up component 60 also includes first, second, and third linear sections 64a, 64b, 64c.

Once aligned, the first build-up component 50 and the second build-up component 60 is pressed against the universal substrate 2. As best seen in FIG. 3B, the first build-up component 50 is pressed downwardly into the universal substrate 2 at the top end 2c. Particularly, the second connection surface 50d of the first build-up component 50 is pressed downwardly into the first connection 11a and first connection surface 12 of universal substrate 2. For diagrammatic purposes, the action of pressing the first build-up component 50 into the universal substrate 2 is denoted by arrows labeled “A” in FIG. 3B. Concurrently, and as best seen in FIG. 3B, the second build-up component 60 is also pressed upwardly into the universal substrate 2 at the bottom end 2d. Particularly, the first connection surface 60c of the second build-up component 60 is pressed upwardly into the second connection 11b and second connection surface 14 of universal substrate 2. For diagrammatic purposes, the action of pressing the second build-up component 60 into the universal substrate 2 is denoted by arrows labeled “B” in FIG. 3B.

Upon such actions, the universal substate 2 flexes and conforms to the profiles of the first build-up component 50 and the second build-up component 60. As such, the universal substrate 2 forms the first non-linear section 32 that has the first connection terminal 32a and the second connection terminal 32b. Concurrently, the universal substrate 2 also forms the second non-linear section 34 that has the first connection terminal 34a and the second connection terminal 34b. At this stage, the universal substrate 2, the first build-up component 50, and the second build-up component 60 are assembled with one another and collectively make-up a single, unitary unit. It should be understood that any suitable adhesives or bonding material may be used to maintain the universal substrate 2, the first build-up component 50, and the second build-up component 60 with one another and to collectively form a single, unitary unit as shown in FIG. 3B.

Once the universal substrate 2, the first build-up component 50, and the second build-up component 60 with assembled with one another, the IC unit 70 may be introduced and engaged with the first build-up component 50 via the solder bump connections 51 (see FIG. 3C). Prior to this assembly, underfill material 72 may be applied to the first build-up component 50. Once the IC unit 70 is bonded to the solder bump connections 51, the heat spreader 74 may also be engaged with the first build-up component 50 and the IC unit 70 (see FIG. 3C). Prior to this assembly, underfill material 72 may also be applied to the first build-up component 50 and the IC unit 70.

Once the universal substrate 2, the first build-up component 50, and the second build-up component 60 with assembled with one another, the package substrate 80 may be introduced and engaged with the second build-up component 60, via solder ball connections 61 (see FIG. 3D). Prior to this assembly, underfill material 72 may be applied to the second build-up component 60 if desired.

As shown in FIGS. 3A-3D, the first build-up component 50 and second build-up component 60 are each pre-fabricated build-up components adhere to the universal substrate 2. It should be noted, however, that build-up components mentioned herein, including first build-up component 50 and second build-up component 60, may be produced and/or manufactured by one or more known processes where each build-up component is a pre-fabricated build-up component that adheres to a universal substrate or is sequentially built up directly on a universal substrate with multiple layers.

In one example, a PCB build-up process may be used to produce and/or manufacture build-up components mentioned herein. In this example, the PCB build-up process laminates a pre-preg or dielectric layer and thin copper foil onto both sides of a universal substrate (e.g., universal substrate 2). PCB build-up process also laser drills holes down to the universal substrate layer on both sides of said universal substrate. PCB build-up process would also pattern a photoresist onto both sides, introduce copper plate to fill vias and traces, remove the photoresist, and etch away remaining non-plated copper foil; such steps of this PCB build-up process would then be repeated sequentially for each set of copper routing layers used in a PCB build-up component.

In another example, semiconductor build-up process may be used to produce and/or manufacture build-up components mentioned herein. While the semiconductor build-up process is similar to the PCB build-up process, the semiconductor build-up process is different because the semiconductor build-up process uses very thin spun-on dielectrics that may be patterned through lithography, which removes the step of laser drilling that is typically needed for the via holes in PCB build-up processes. The vias and routing layer metallization in semiconductor build-up processes are typically done via metal sputtering on top of a patterned photoresist, which allows non-patterned metal to be removed through a “lift-off” process rather than etching.

It should be noted that while PoP 1 illustrates two electronic devices (i.e., IC unit 70 and package substrate 80), any suitable number of package-on-package configurations or device-on-device product configurations may be used along with any suitable number of universal substrates 2.

In one example, and as best seen in FIG. 4, an alternative PoP 100 may include two universal substrates that are used to interconnect a first package 100-1 and a second package 100-2 with one another. In this example, first package 100-1 includes a universal substrate 102-1 that operably engages with a first build-up component 150-1 and a second build-up component 160-1. First package 100-1 also includes two electronic devices, an IC unit 170-1 and a package substrate 180-1, that are connected with one another via the universal substrate 102-1. Similarly, in this same example, second package 100-2 includes a universal substrate 102-2 that operably engages with a first build-up component 150-2 and a second build-up component 160-2. Second package 100-2 also includes two electronic devices, an IC unit 170-2 and a package substrate 180-2, that are connected with one another via the universal substrate 102-2.

In this embodiment, both the first package 100-1 and second package 100-2 are substantially similar to one another and may communicate with one another via the universal substrate 102-1, 102-2. In one instance, IC unit 170-1 and package substrate 180-1 may communicate with one another inside of first package 100-1 by the universal substrate 102-1 while universal substrate 102-1 includes non-linear and/or curvilinear sections along the length of said universal substrate 102-1. In another instance, IC unit 170-2 and package substrate 180-2 may communicate with one another inside of first package 100-2 by the universal substrate 102-2 while universal substrate 102-2 includes non-linear and/or curvilinear sections along the length of said universal substrate 102-2. In yet another instance, one or more of the electronic devices of the first package 100-1 may communicate with one or more of the electronic devices of the second package 100-2 by the universal substrates 102-1, 102-2 while universal substrates 102-1, 102-2 include non-linear and/or curvilinear sections along the length of said universal substrates 102-1, 102-2.

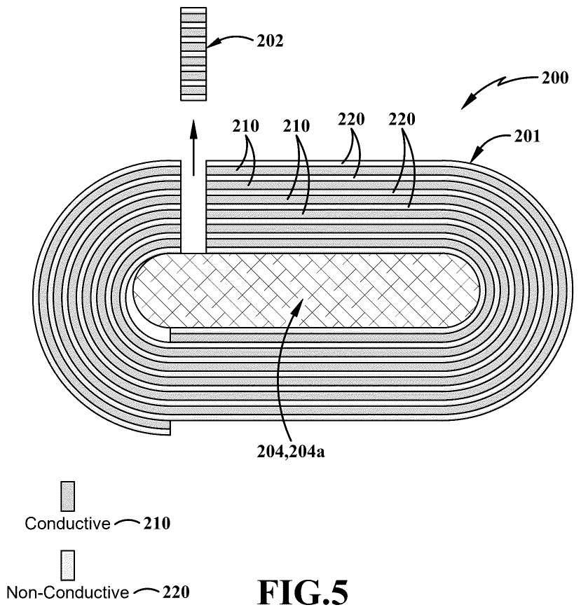

FIG. 5 illustrate a fabrication process 200 for creating a batch product 201 that may be wafered into one or more universal substrates described and illustrated herein (e.g., universal substrate 2). Such components of the used in fabricating a batch product 201 for the fabrication process 200 are discussed in greater detail below.

Initially, a preform or template 204 that defines a predetermined and/or desired outer profile for fabricating a batch universal product 201 (hereinafter “batch product”) that may be wafered into one or more universal substrates described and illustrated herein (similar to universal substrate 2). As best seen in FIG. 5, the preform 204 includes an outer surface 204A that is continuous along the entire length of the preform 204 for holding one or more conductors of a batch product 201, which is discussed in greater detail below. In the present disclosure, a first end of the batch product 201 is engaged with the outer surface 204A of the preform 204, and a second end of the batch product 201 is opposite to the first end and is spaced apart from the preform 204 due to the batch product 201 being wrapped about the preform 204.

Continuing with fabrication process 200, a plurality of conductors 210 that form the batch product 201 are wound and/or wrapped about the outer surface 204A of the preform 204 in a desired orientation and/or arrangement dictated by the implementation of one or more universal substrates wafered from the batch product 201 (see FIG. 5). It should be noted that the plurality of conductors 210 may be conductors described and illustrated herein (e.g., plurality of conductors 10). In one exemplary embodiment, each conductor of the plurality of conductors 210 that is wound and/or wrapped about the outer surface 204A of the preform 204 may include a shielding and/or nonconductive material that protects and isolates the conductor from the external environment. In another exemplary embodiment, each conductor of the plurality of conductors 210 that is wound and/or wrapped about the outer surface 204A of the preform 204 may be a bare conductor that is free from any having any shielding and/or nonconductive material that protects and isolates the conductor from the external environment.

Once the plurality of conductors 210 are wound about the preform 204, a nonconductive matrix or dielectric material 220 may then be introduced to the preform 204 and the plurality of conductors 210. As best seen in FIG. 5, the nonconductive matrix 820 is applied to the preform 204 and the plurality of conductors 810 wherein the nonconductive matrix 220 permeates the interstitial space between the plurality of wires 210. Such permeation of the nonconductive matrix 220 allows the nonconductive matrix 220 to bond with the plurality of conductors 210 to hold and maintain the plurality of conductors 210 with one another at the desired shape of the preform 204 to create the batch product 201. Such permeation of the nonconductive matrix 220 also separates and/or isolates the plurality of conductors 210 from one another in a longitudinal direction and a lateral direction as previously discussed above. It should be noted that the nonconductive matrix and/or dielectric material may be any nonconductive matrix described and illustrated herein (e.g., nonconductive matrix 20).

Once the batch product 201 is formed, a section or individual universal substrate 202 of the batch product 201 may be removed from the batch product 201 for creating one or more individual universal substrates (e.g., universal substrate 202) (see FIG. 5). Once removed, the universal substrate 202 of the batch product 201 may then be cut and/or wafered into one or more individual universal substrates having a desired parameters dictated by the implementation of the one or more individual universal substrates. It should be understood that any suitable equipment and/or tools may be used to remove and/or wafer one or more individual universal substrates 202 from the batch product 201. It should also be noted that the one or more individual universal substrates 202 may be any universal substrate discussed herein, including universal substrate 2, 102-1, 102-2.

Upon such wafering of the one or more universal substrates 202, additional tools and/or equipment may be used to machine and/or form various features into one or more universal substrates 202. In one exemplary embodiment, tools and/or equipment may be used to machine linear, non-linear, and/or stepped profiles into one or more universal substrates 202. In another exemplary embodiment, tools and/or equipment may be used to remove one or more conductors 210 and nonconductive matrix 220 from one or more universal substrates 202 to define apertures, vias, and/or voids in the one or more universal substrates 202.

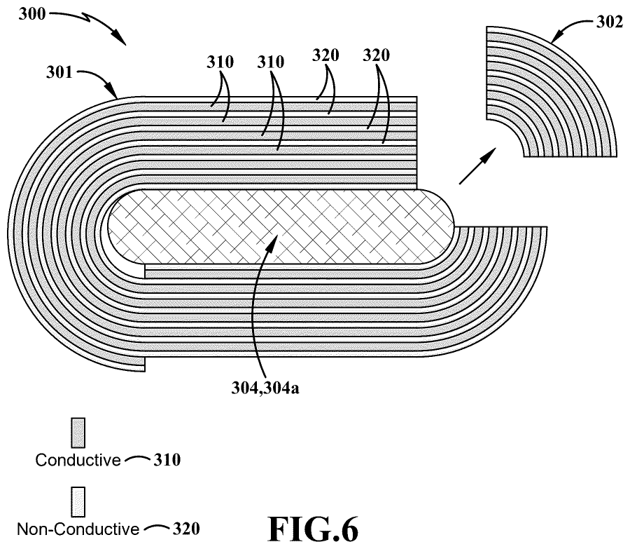

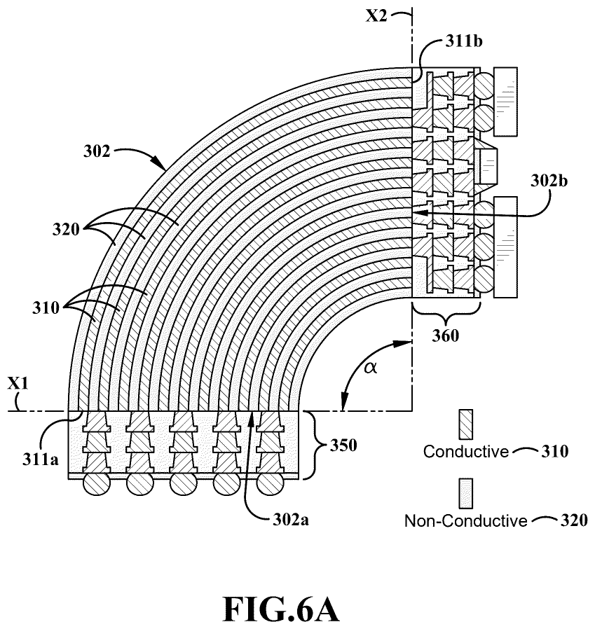

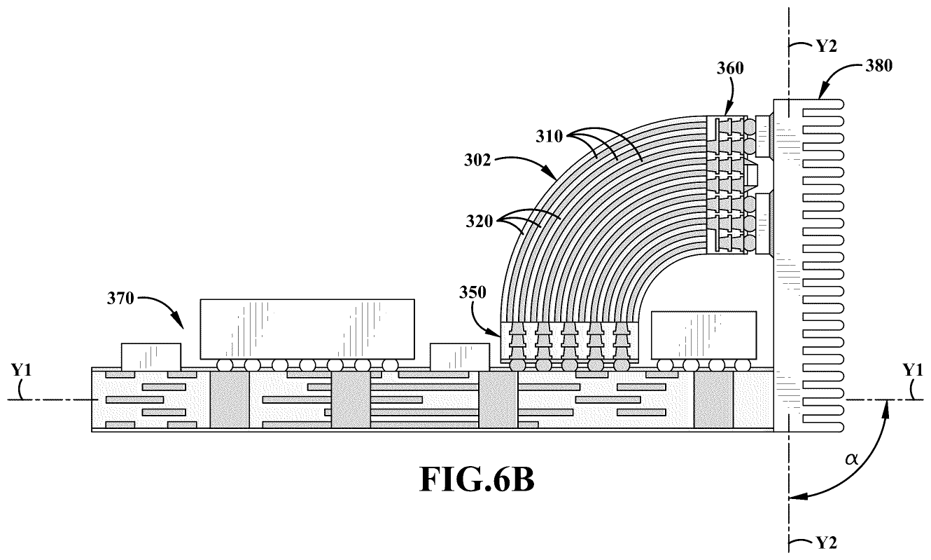

FIG. 6 illustrate another fabrication process 300 for creating a batch product 301 that may be wafered into one or more universal substrates described and illustrated herein. Such components of the used in fabricating a batch product 301 for the fabrication process 300 are discussed in greater detail below.

Initially, a preform or template 304 that defines a predetermined and/or desired outer profile for fabricating a batch universal product 301 (hereinafter “batch product”) that may be wafered into one or more universal substrates described and illustrated herein (similar to universal substrate 2). As best seen in FIG. 6, the preform 304 includes an outer surface 304A that is continuous along the entire length of the preform 304 for holding one or more conductors of a batch product 301, which is discussed in greater detail below. Similar to batch product 301, a first end of the batch product 301 is engaged with the outer surface 304A of the preform 304, and a second end of the batch product 301 is opposite to the first end and is spaced apart from the preform 304 due to the batch product 301 being wrapped about the preform 304. In the illustrated embodiment, the preform 304 defines a circular and/or round cross-sectional shape for creating round and/or non-linear universal substrates. In other exemplary embodiments, a preform may define any suitable cross-sectional shape for creating various types of universal substrates dictated by the implementation of said universal substrates.

Continuing with fabrication process 300, a plurality of conductors 310 that form the batch product 301 are wound and/or wrapped about the outer surface 304A of the preform 304 in a desired orientation and/or arrangement dictated by the implementation of one or more universal substrates wafered from the batch product 301 (see FIG. 6). It should be noted that the plurality of conductors 310 may be conductors described and illustrated herein (e.g., plurality of conductors 10). In one exemplary embodiment, each conductor of the plurality of conductors 310 that is wound and/or wrapped about the outer surface 304A of the preform 304 may include a shielding and/or nonconductive material that protects and isolates the conductor from the external environment. In another exemplary embodiment, each conductor of the plurality of conductors 310 that is wound and/or wrapped about the outer surface 304A of the preform 304 may be a bare conductor that is free from any having any shielding and/or nonconductive material that protects and isolates the conductor from the external environment.

Once the plurality of conductors 310 are wound about the preform 304, a nonconductive matrix or dielectric material 320 may then be introduced to the preform 304 and the plurality of conductors 310. As best seen in FIG. 6, the nonconductive matrix 320 is applied to the preform 304 and the plurality of conductors 310 wherein the nonconductive matrix 320 permeates the interstitial space between the plurality of wires 310. Such permeation of the nonconductive matrix 320 allows the nonconductive matrix 320 to bond with the plurality of conductors 310 to hold and maintain the plurality of conductors 310 with one another at the desired shape of the preform 304 to create the batch product 301. Such permeation of the nonconductive matrix 320 also separates and/or isolates the plurality of conductors 310 from one another in a longitudinal direction and a lateral direction as previously discussed above. It should be noted that the nonconductive matrix and/or dielectric material may be any nonconductive matrix described and illustrated herein (e.g., nonconductive matrix 20).

Once the batch product 301 is formed, a section or individual universal substrate 302 of the batch product 301 may be removed from the batch product 301 (see FIG. 6). In this embodiment, the individual universal substrate 302 of batch product 301 defines a curvilinear shape and/or arcuate shape based on the outer surface 304A of the preform 304.

Such curvilinear shape and/or arcuate shape of the individual universal substrate 302 is considered advantageous for connecting at least two radiofrequency (RF) devices or similar electronic devices with one another for directing and sending electronic signals between the at least two RF devices by the universal substrate 302. As best seen in FIGS. 6A-6B, the universal substrate 302 includes a first end 302a and a second end 302b that is opposite to the first end 302a. Universal substrate 302 also includes a first connection end 311a at each conductor of the plurality of conductors 310 proximate to the first end 302a, and a second connection end 311b at each conductor of the plurality of conductors 310 proximate to the second end 302b.

In this particular embodiment, the first end 302a and the first connection ends 311a lie on a first plane or axis; such first axis is denoted by a dashed line labeled “X1” in FIG. 6A. Additionally, the second end 302b and the second connection ends 311b lie on a second plane or axis; such second axis is denoted by a dashed line labeled “X2” in FIG. 6A. In this embodiment, the first connection ends 311a and the second connection ends 311b are defined at a first angle (labeled α in FIG. 6A) measured between the first axis “X1” and the second axis “X2”. In one example, the first angle may a range between 0 degrees up to about 90 degrees. In another example, the first angle may be approximately 90 degrees. It should be understood that the first connection ends 311a and the second connection ends 311b may be defined at any suitable angle based on the intended use of universal substrate 302, including the locations and/or positions of electronic devices.

In this particular embodiment, universal substrate 302 is bonded to a first build-up component 350 at the first connection ends 311a and bonded to a second build-up component 360 at the second connection ends 311b; it should be understood that first build-up component 350 and second build-up component 360 are similar in function in comparison to the first build-up component 50 and second build-up component 60 mentioned above. Based on the structural configuration of the universal substrate 302, the first build-up component 350 and the second build-up component 360 are also defined at the first angle.

With specific reference to FIG. 6B, the universal substrate 302 interconnects a first package or electronic device 370 with a second package or electronic device 380 to form a PoP. In this embodiment, the first package 370 is positioned along a first axis or plane (denoted by a dashed line labeled “Y1” in FIG. 6B) that is parallel with the first axis “X1” of the first connection ends 311a. Similarly, the second package 380 is positioned along a second axis or plane (denoted by a dashed line labeled “Y2” in FIG. 6B) that is parallel with the second axis “X2” of the second connection ends 311b. With such structural configuration of universal substrate 302, the first package 370 and the second package 380 are able to be interconnected with one another at the first angle.

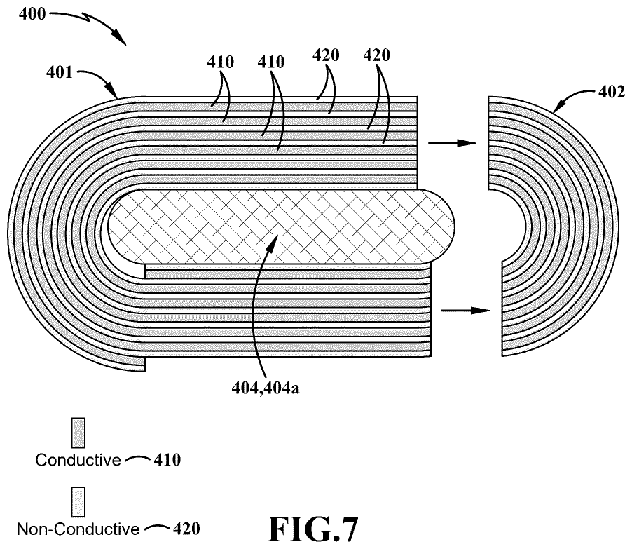

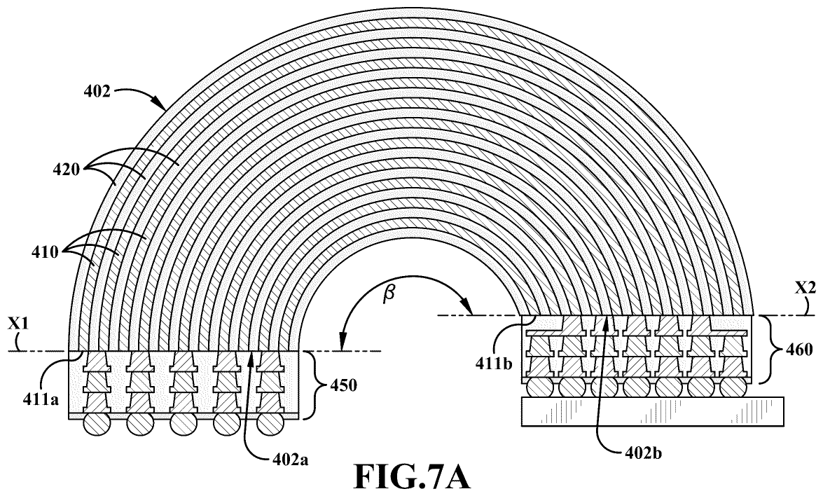

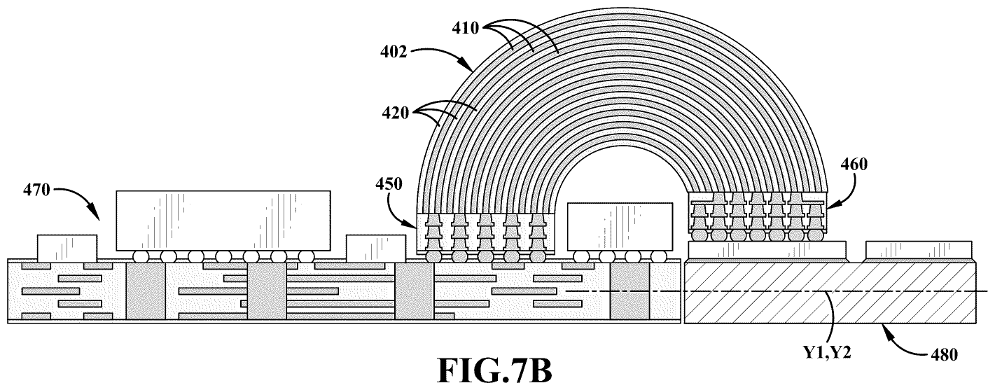

FIG. 7 illustrate another fabrication process 400 for creating a batch product 401 that may be wafered into one or more universal substrates described and illustrated herein. Such components of the used in fabricating a batch product 401 for the fabrication process 400 are discussed in greater detail below.

Initially, a preform or template 404 that defines a predetermined and/or desired outer profile for fabricating a batch universal product 401 (hereinafter “batch product”) that may be wafered into one or more universal substrates described and illustrated herein (similar to universal substrate 2). As best seen in FIG. 7, the preform 404 includes an outer surface 404A that is continuous along the entire length of the preform 404 for holding one or more conductors of a batch product 401, which is discussed in greater detail below. Similar to batch product 301, a first end of the batch product 401 is engaged with the outer surface 404A of the preform 404, and a second end of the batch product 401 is opposite to the first end and is spaced apart from the preform 404 due to the batch product 401 being wrapped about the preform 404. In the illustrated embodiment, the preform 404 defines a circular and/or round cross-sectional shape for creating round and/or non-linear universal substrates. In other exemplary embodiments, a preform may define any suitable cross-sectional shape for creating various types of universal substrates dictated by the implementation of said universal substrates.

Continuing with fabrication process 400, a plurality of conductors 410 that form the batch product 401 are wound and/or wrapped about the outer surface 404A of the preform 404 in a desired orientation and/or arrangement dictated by the implementation of one or more universal substrates wafered from the batch product 401 (see FIG. 7). It should be noted that the plurality of conductors 410 may be conductors described and illustrated herein (e.g., plurality of conductors 10). In one exemplary embodiment, each conductor of the plurality of conductors 410 that is wound and/or wrapped about the outer surface 404A of the preform 404 may include a shielding and/or nonconductive material that protects and isolates the conductor from the external environment. In another exemplary embodiment, each conductor of the plurality of conductors 410 that is wound and/or wrapped about the outer surface 404A of the preform 404 may be a bare conductor that is free from any having any shielding and/or nonconductive material that protects and isolates the conductor from the external environment.

Once the plurality of conductors 410 are wound about the preform 404, a nonconductive matrix or dielectric material 420 may then be introduced to the preform 404 and the plurality of conductors 410. As best seen in FIG. 7, the nonconductive matrix 420 is applied to the preform 404 and the plurality of conductors 410 wherein the nonconductive matrix 420 permeates the interstitial space between the plurality of wires 410. Such permeation of the nonconductive matrix 420 allows the nonconductive matrix 420 to bond with the plurality of conductors 410 to hold and maintain the plurality of conductors 410 with one another at the desired shape of the preform 404 to create the batch product 401. Such permeation of the nonconductive matrix 420 also separates and/or isolates the plurality of conductors 410 from one another in a longitudinal direction and a lateral direction as previously discussed above. It should be noted that the nonconductive matrix and/or dielectric material may be any nonconductive matrix described and illustrated herein (e.g., nonconductive matrix 20).

Once the batch product 401 is formed, a section or individual universal substrate 402 of the batch product 401 may be removed from the batch product 401 (see FIG. 7). In this embodiment, the individual universal substrate 402 of batch product 401 defines a curvilinear shape and/or arcuate shape based on the outer surface 404A of the preform 404.

Such curvilinear shape and/or arcuate shape of the individual universal substrate 402 is considered advantageous for connecting at least two radiofrequency (RF) devices or similar electronic devices with one another for directing and sending electronic signals between the at least two RF devices by the universal substrate 402. As best seen in FIGS. 7A-7B, the universal substrate 402 includes a first end 402a and a second end 402b that is opposite to the first end 402a. Universal substrate 402 also includes a first connection end 411a at each conductor of the plurality of conductors 410 proximate to the first end 402a, and a second connection end 411b at each conductor of the plurality of conductors 410 proximate to the second end 402b.

In this particular embodiment, the first end 402a and the first connection ends 411a lie on a first plane or axis; such first axis is denoted by a dashed line labeled “X1” in FIG. 7A. Additionally, the second end 402b and the second connection ends 411b lie on a second plane or axis; such second axis is denoted by a dashed line labeled “X2” in FIG. 7A. In this embodiment, the first connection ends 411a and the second connection ends 411b are defined at a second angle (labeled β in FIG. 7A) measured between the first axis “X1” and the second axis “X2”. In one example, the second angle may a range between 0 degrees up to about 180 degrees. In another example, the second angle may be approximately 180 degrees. It should be understood that the first connection ends 411a and the second connection ends 411b may be defined at any suitable angle based on the intended use of universal substrate 402, including the locations and/or positions of electronic devices.

In this particular embodiment, universal substrate 402 is bonded to a first build-up component 450 at the first connection ends 411a and bonded to a second build-up component 460 at the second connection ends 411b; it should be understood that first build-up component 450 and second build-up component 460 are similar in function in comparison to the first build-up component 50 and second build-up component 60 mentioned above. Based on the structural configuration of the universal substrate 402, the first build-up component 450 and the second build-up component 460 are also defined at the second angle.

With specific reference to FIG. 7B, the universal substrate 402 interconnects a first package or electronic device 470 with a second package or electronic device 480 to form a PoP. In this embodiment, the first package 470 is positioned along a first axis or plane (denoted by a dashed line labeled “Y1” in FIG. 7B) that is parallel with the first axis “X1” of the first connection ends 411a. Similarly, the second package 480 is positioned along a second axis or plane (denoted by a dashed line labeled “Y2” in FIG. 7B) that is parallel with the second axis “X2” of the second connection ends 411b. With such structural configuration of universal substrate 402, the first package 470 and the second package 480 are able to be interconnected with one another at the second angle.

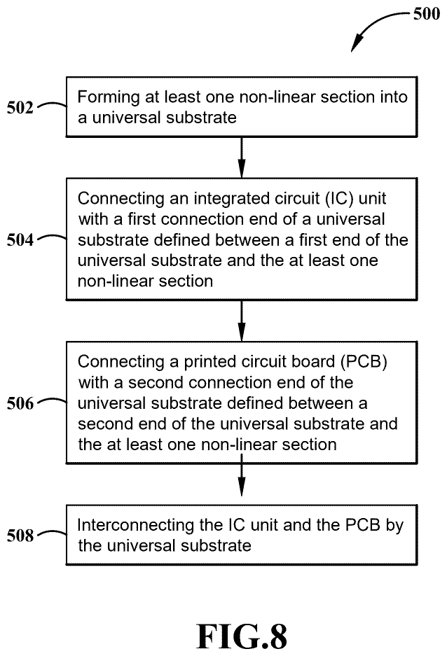

FIG. 8 is a diagrammatic flowchart of method 500. An initial step 502 of method 500 includes forming at least one non-linear section into a universal substate. Another step 504 of method 500 includes connecting an integrated circuit (IC) unit with a first connection end of a universal substrate defined between a first end of the universal substrate and the at least one non-linear section. Another step 506 of method 500 includes connecting a printed circuit board (PCB) with a second connection end of the universal substrate defined between a second end of the universal substrate and the at least one non-linear section. Another step 508 of method 500 includes interconnecting the IC unit and the PCB by the universal substrate.

In other exemplary embodiments, method 500 may include optional or further steps. In one exemplary embodiment, method 500 may further include steps of aligning a first build-up component and a second build-up component with one another; aligning the universal substrate between the first build-up component and the second build-up component; and joining the first build-up component, the second build-up component, and the universal substate together; wherein the step forming the at least one non-linear section into the universal substate further includes that the at least one non-linear section is formed between the first build-up component and the second build-up component. In another exemplary embodiment, method 500 may further include that the first connection end is positioned at a range of angles relative to the second connection end from about 0 degrees to about 180 degrees.

It should be understood that any suitable range or values of resistivity may be used for any nonconductive matrix or material mentioned herein. In one example, an exemplary resistivity for a nonconductive matrix or material mentioned herein includes at least 10⁸ ohms-cm of resistivity. It should also be understood that any suitable range or values of resistivity for any conductive members or material mentioned herein. In one example, an exemplary resistivity for a conductive members or material mentioned herein includes at least 10⁻⁴ ohms-cm of resistivity. Examples of suitable conductors or conductive material that may be used for any conductive members or material mentioned herein include, but are not limited to, copper, gold, silver, and other similar conductors or conductive material that may be electrically conductive or thermally conductive.

Various inventive concepts may be embodied as one or more methods, of which an example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The articles “a” and “an,” as used herein in the specification and in the claims, unless clearly indicated to the contrary, should be understood to mean “at least one. ” The phrase “and/or,” as used herein in the specification and in the claims (if at all), should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc. As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

While components of the present disclosure are described herein in relation to each other, it is possible for one of the components disclosed herein to include inventive subject matter, if claimed alone or used alone. In keeping with the above example, if the disclosed embodiments teach the features of components A and B, then there may be inventive subject matter in the combination of A and B, A alone, or B alone, unless otherwise stated herein.

As used herein in the specification and in the claims, the term “effecting” or a phrase or claim element beginning with the term “effecting” should be understood to mean to cause something to happen or to bring something about. For example, effecting an event to occur may be caused by actions of a first party even though a second party actually performed the event or had the event occur to the second party. Stated otherwise, effecting refers to one party giving another party the tools, objects, or resources to cause an event to occur. Thus, in this example a claim element of “effecting an event to occur” would mean that a first party is giving a second party the tools or resources needed for the second party to perform the event, however the affirmative single action is the responsibility of the first party to provide the tools or resources to cause said event to occur.

When a feature or element is herein referred to as being “on” another feature or element, it can be directly on the other feature or element or intervening features and/or elements may also be present. In contrast, when a feature or element is referred to as being “directly on” another feature or element, there are no intervening features or elements present. It will also be understood that, when a feature or element is referred to as being “connected”, “attached” or “coupled” to another feature or element, it can be directly connected, attached or coupled to the other feature or element or intervening features or elements may be present. In contrast, when a feature or element is referred to as being “directly connected”, “directly attached” or “directly coupled” to another feature or element, there are no intervening features or elements present. Although described or shown with respect to one embodiment, the features and elements so described or shown can apply to other embodiments. It will also be appreciated by those of skill in the art that references to a structure or feature that is disposed “adjacent” another feature may have portions that overlap or underlie the adjacent feature.

Spatially relative terms, such as “under”, “below”, “lower”, “over”, “upper”, “above”, “behind”, “in front of”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if a device in the figures is inverted, elements described as “under” or “beneath” other elements or features would then be oriented “over” the other elements or features. Thus, the exemplary term “under” can encompass both an orientation of over and under. The device may be otherwise oriented (rotated 90 degrees or at other orientations) and the spatially relative descriptors used herein interpreted accordingly. Similarly, the terms “upwardly”, “downwardly”, “vertical”, “horizontal”, “lateral”, “transverse”, “longitudinal”, and the like are used herein for the purpose of explanation only unless specifically indicated otherwise.

Although the terms “first” and “second” may be used herein to describe various features/elements, these features/elements should not be limited by these terms, unless the context indicates otherwise. These terms may be used to distinguish one feature/element from another feature/element. Thus, a first feature/element discussed herein could be termed a second feature/element, and similarly, a second feature/element discussed herein could be termed a first feature/element without departing from the teachings of the present invention.

An embodiment is an implementation or example of the present disclosure. Reference in the specification to “an embodiment,” “one embodiment,” “some embodiments,” “one particular embodiment,” “an exemplary embodiment,” or “other embodiments,” or the like, means that a particular feature, structure, or characteristic described in connection with the embodiments is included in at least some embodiments, but not necessarily all embodiments, of the invention. The various appearances “an embodiment,” “one embodiment,” “some embodiments,” “one particular embodiment,” “an exemplary embodiment,” or “other embodiments,” or the like, are not necessarily all referring to the same embodiments.

If this specification states a component, feature, structure, or characteristic “may”, “might”, or “could” be included, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

As used herein in the specification and claims, including as used in the examples and unless otherwise expressly specified, all numbers may be read as if prefaced by the word “about” or “approximately,” even if the term does not expressly appear. The phrase “about”, “substantially”, or “approximately” may be used when describing magnitude and/or position to indicate that the value and/or position described is within a reasonable expected range of values and/or positions. For example, a numeric value may have a value that is +/−0.1% of the stated value (or range of values), +/−1% of the stated value (or range of values), +/−2% of the stated value (or range of values), +/−5% of the stated value (or range of values), +/−10% of the stated value (or range of values), etc. Any numerical range recited herein is intended to include all sub-ranges subsumed therein.

Additionally, the method of performing the present disclosure may occur in a sequence different than those described herein. Accordingly, no sequence of the method should be read as a limitation unless explicitly stated. It is recognizable that performing some of the steps of the method in a different order could achieve a similar result.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures.

To the extent that the present disclosure has utilized the term “invention” in various titles or sections of this specification, this term was included as required by the formatting requirements of word document submissions pursuant the guidelines/requirements of the United States Patent and Trademark Office and shall not, in any manner, be considered a disavowal of any subject matter.

In the foregoing description, certain terms have been used for brevity, clearness, and understanding. No unnecessary limitations are to be implied therefrom beyond the requirement of the prior art because such terms are used for descriptive purposes and are intended to be broadly construed.

Moreover, the description and illustration of various embodiments of the disclosure are examples and the disclosure is not limited to the exact details shown or described.

What is claimed is:

1. A universal substrate for a printed circuit board (PCB) package, the universal substrate comprising:
a first end and a second end opposite to the first end;
a plurality of conductors located between the first end and the second end, the plurality of conductors having a first connection end, a second connection end opposite to the first connection end, and a plurality of conductive pathways defined between the first connection end and the second connection end;
a nonconductive matrix surrounding the plurality of conductors and configured to isolate each conductor of the plurality of conductors from one another along an axis that is perpendicular to the plurality of pathways; and
at least one non-linear section defined between the first connection end and the second connection end;
wherein at least two devices of the PCB package have conductivity at any two positions along the first connection end and the second connection end.

2. The universal substrate of claim 1, wherein the at least one non-linear section is a curved section and the at least two coaxial devices of the PCB package are free from being conductive along the at least one non-linear section.

3. The universal substrate of claim 1, wherein the at least one non-linear section is a continuous curved section and the at least two coaxial devices of the PCB package are conductive along the at least one non-linear section.

4. The universal substrate of claim 1, further comprising:
a first connection section defined between the first end of the universal substrate and the at least one non-linear section; and
a second connection section defined between the second end of the universal substrate that is opposite to the first end and the at least one non-linear section;
wherein the second connection section is positioned above the first connection section.

5. The universal substrate of claim 4, wherein the first connection section comprises:
a first connection terminal that is a part of the first connection end; and
a second connection terminal opposite to the first connection terminal and is a part of the second connection end; and
wherein the second connection section comprises:
a third connection terminal that is a part of the first connection end; and
a fourth connection terminal opposite to the third connection terminal and is a part of the second connection end;
wherein the third connection terminal and the fourth connection terminal are each positioned above the first connection terminal and the second connection terminal relative to the at least one non-linear section.

6. The universal substrate of claim 4, wherein the at least one non-linear section further comprises:
a first non-linear section defined between a first connection section and a second connection section; and
a second non-linear section defined between the second connection section and a third connection section;
wherein the first connection section, the second connection section, and the third connection section are each substantially linear, and wherein the second connection section is positioned above the first connection section and the third connection section.

7. The universal substrate of claim 1, wherein the first connection end is substantially parallel to the second connection end.

8. The universal substrate of claim 1, wherein the first connection end is positioned at a range of angles relative to the second connection end from about 0 degrees to about 90 degrees.

9. The universal substrate of claim 1, wherein the first connection end is positioned at a range of angles relative to the second connection end from about 0 degrees to about 180 degrees.

10. The universal substrate of claim 1, wherein the universal substrate is formed from a resilient, flexible material.

11. A printed circuit board (PCB) package, comprising:
an integrated circuit (IC) unit placed at a first position in the PCB package;
a PCB unit placed at a second position in the PCB package; and
a universal substrate placed at a third position in the PCB package and interconnecting the IC unit and PCB with one another; wherein the universal substrate comprises:
a first end and a second end opposite to the first end;
a plurality of conductors located between the first end and the second end, the plurality of conductors having a first connection end that connects with the IC unit, a second connection end opposite to the first connection end and that connects with the PCB unit, and a plurality of conductive pathways defined between the first connection end and the second connection end;
a nonconductive matrix surrounding the plurality of conductors and configured to isolate each conductor of the plurality of conductors from one another along an axis that is perpendicular to the plurality of pathways; and
at least one non-linear section defined between the first connection end and the second connection end.

12. The PCB package of claim 11, wherein the at least one non-linear section is a continuous curved section, and wherein the IC unit and PCB of the PCB package are free from being conductive along the at least one non-linear section or are conductive along the at least one non-linear section.

13. The PCB package of claim 11, wherein the universal substrate further comprises:
a first connection section defined between the first end of the universal substrate and the at least one non-linear section; and
a second connection section defined between the second end of the universal substrate that is opposite to the first end and the at least one non-linear section;
wherein the second connection section is positioned above the first connection section.

14. The PCB package of claim 11, wherein the first connection end is substantially parallel to the second connection end.

15. The PCB package of claim 11, wherein the first connection end is positioned at a range of angles relative to the second connection end from about 0 degrees to about 90 degrees.

16. The PCB package of claim 11, wherein the first connection end is positioned at a range of angles relative to the second connection end from about 0 degrees to about 180 degrees.

17. The PCB package of claim 11, wherein the universal substrate is formed from a resilient, flexible material.

18. A method, comprising:
forming at least one non-linear section into a universal substate;
connecting an integrated circuit (IC) unit with a first connection end of a universal substrate defined between a first end of the universal substrate and the at least one non-linear section;
connecting a printed circuit board (PCB) with a second connection end of the universal substrate defined between a second end of the universal substrate and the at least one non-linear section; and
interconnecting the IC unit and the PCB by the universal substrate.

19. The method of claim 18, further comprising:
aligning a first build-up component and a second build-up component with one another;
aligning the universal substrate between the first build-up component and the second build-up component; and
joining the first build-up component, the second build-up component, and the universal substate together;
wherein the step forming the at least one non-linear section into the universal substate further includes that the at least one non-linear section is formed between the first build-up component and the second build-up component.

20. The method of claim 18, wherein the first connection end is positioned at a range of angles relative to the second connection end from about 0 degrees to about 180 degrees.
